(19) United States
(12) Patent Application Publication
(10) Pub. No.: US 2015/0072515 A1
(43) Pub. Date: Mar. 12, 2015

(54) LASER ABLATION METHOD AND RECIPE FOR SACRIFICIAL MATERIAL PATTERNING AND REMOVAL

(71) Applicants: Rajendra C. Dias, Phoenix, AZ (US); Lars D. Skoglund, Chandler, AZ (US); Anil R. Indluru, Tempe, AZ (US); Edward R. Prack, Phoenix, AZ (US); Danish Faruqui, Chandler, AZ (US); Tyler N. Osborn, Gilbert, AZ (US)

(72) Inventors: Rajendra C. Dias, Phoenix, AZ (US); Lars D. Skoglund, Chandler, AZ (US); Anil R. Indluru, Tempe, AZ (US); Edward R. Prack, Phoenix, AZ (US); Danish Faruqui, Chandler, AZ (US); Tyler N. Osborn, Gilbert, AZ (US)

(21) Appl. No.: 14/021,954

(22) Filed: Sep. 9, 2013

(51) Int. Cl. H01L 23/00

(52) U.S. Cl. CPC H01L 24/11; H01L 2224/1181; H01L 2224/11848; H01L 2924/40102; H01L 2924/40501; H01L 2924/14; H01L 2924/403
USPC 438/613

(57) ABSTRACT

A method including introducing a passivation material over contact pads on a surface of an integrated circuit substrate; patterning a sacrificial material on the passivation material to define openings in the sacrificial material to the contact pads; introducing solder to the contact pads; and after introducing the solder, removing the sacrificial material with the proviso that, where the sacrificial material is a photosensitive material, removing comprises using temporally coherent electromagnetic radiation. A method including introducing a passivation material over contact pads; exposing the contact pads; patterning a photosensitive material on the passivation material; introducing solder to the contact pads; and after introducing the solder, removing the photosensitive material using temporally coherent electromagnetic radiation. A method including introducing a passivation material over contact pads; exposing the contact pads; patterning a non-photosensitive material on the passivation material; introducing solder to the contact pads; and after introducing the solder, removing the non-photosensitive material.

### FIELD

Integrated circuit packaging.

### BACKGROUND

One method of connecting a semiconductor die to a substrate such as a package substrate is through a soldered connection between a contact pad of the die and a contact pad of the substrate (e.g., a package substrate). An underfill material of, for example, an epoxy resin may be disposed around the soldered connection to improve, among other things, temperature cycling capability. One technique for introducing an underfill material is to introducing it to the die at the wafer level (i.e., before dicing of the wafer into individual dice). A typical process includes applying an underfill material as a blanket over a wafer surface including the over contacts. The underfill material is then baked/cured and then planarized to a plane of the contact pads to expose the contact pads. A photoresist is then introduced and patterned leaving the contact pads exposed. This is followed by the application of a soldered paste to the contact pads and reflow to establish the solder connection to the individual contact pads. The photoresist material is then removed leaving the solder on the contact pads and the underfill material surrounding the contact pads.

To expose the contact pads through underfill material, current methods involve grinding, chemical mechanical polish or fly cut techniques. These methods produce residues that can embed in the underfill material between pads and potentially damaged fragile dielectric materials on the die. In addition, the current techniques to remove photoresist material from the wafer after solder reflow use wet (aqueous or organic) strippers. These strippers have a tendency to etch the backside of the wafer, solder and other film material. Photoresist materials are difficult to remove using conventional strippers because they generally have a high density of cross-linking to withstand a solder reflow temperature (e.g., 260° C.) and be compatible with a solder paste material and other processing materials. The more cured the photoresist material, the more cross-linking and the more difficult it is to remove without damaging other materials on the wafer. The temperature associated with solder reflow often contributes to the curing of the photoresist material.

### BRIEF DESCRIPTION OF THE DRAWINGS

FIG. 1 shows a side view of a portion of a wafer including a contact pad on a surface and a passivation material on the surface and over the contact pad.

FIG. 2 shows the structure of FIG. 1 following the removal of passivation material to expose the contact pad.

FIG. 3 shows the structure of FIG. 2 following the introduction of sacrificial material to a thickness suitable for solder introduction on the contact pads.

FIG. 4 shows the structure of FIG. 3 following the formation of an opening in the sacrificial material to the contact pad.

FIG. 5 shows the structure of FIG. 4 following the introduction of solder material.

FIG. 6 shows the structure of FIG. 5 following the formation of a solder bump.

FIG. 7 shows the structure of FIG. 6 following the removal of the sacrificial material.

FIG. 8 shows a side view portion of a silicon wafer including a contact pad on a surface and a passivation material on the surface and over the contact pad according to a second embodiment.

FIG. 9 shows the structure of FIG. 8 following planarization or ablating of the passivation material to expose the contact pad and bring the blanket layer of the underfill material to a plane of the contact pad.

FIG. 10 shows the structure of FIG. 9 following the introduction and patterning of sacrificial material on the passivation material with an opening to the contact pad and a solder material formed in the opening.

FIG. 11 shows the structure of FIG. 10 following the formation of a solder bump.

FIG. 12 shows the structure of FIG. 11 following the removal of the sacrificial material.

FIG. 13 shows a perspective top, side view of a laser ablation system including a pulsed-wave ultraviolet laser.

FIG. 14 shows a perspective top, side view of a laser ablation system including a constant wave excimer projection ultraviolet laser.

FIG. 15 illustrates a schematic illustration of a computing device.

### DETAILED DESCRIPTION

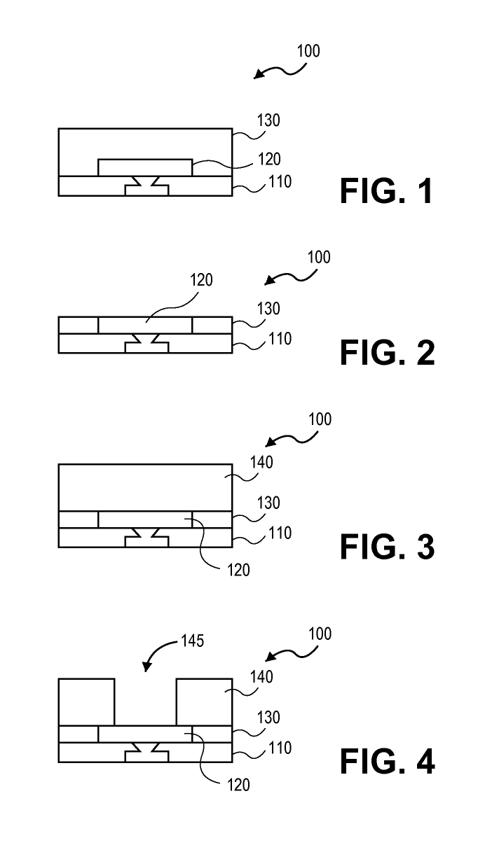

FIGS. 1-7 describe an embodiment of a process of introducing a passivation material on a wafer, patterning a sacrificial material on the passivation material to expose contact pads on the wafer, introducing solder and removing the sacrificial material after solder reflow. FIG. 1 shows structure 100 that is, for example, a side view of a portion of a wafer. Wafer 110 is, for example, a silicon wafer with many integrated circuit dice formed therein. Each die has a number of contact pads on a surface to connect the die to, for example, a substrate package after dicing. FIG. 1 shows one contact pad, contact pad 120 on a surface of wafer 110. Contact pad 120 is, for example, a copper pad.

Overlying contact pad 120 as a blanket over, for example, a surface of wafer 110 is passivation material 130. Passivation material 130 is, for example, any fabrication passivation such as inorganic passivation (such as silicon nitride or silicon oxinitride), or organic passivation (such as polyimide). In another embodiment, passivation material is an underfill material of, for example, an epoxy material. Representative epoxy material includes an amine epoxy, imidizole epoxy, a phenolic epoxy or an anhydride epoxy. Other examples of underfill material include a bismalleimide type underfill, a polybenzoxazine (PBO) underfill, or a polynorborene underfill. Additionally, the passivation material 130 may include a filler material such as silica.

Following the introduction of passivation material 130 on wafer 110, where necessary, the passivation material is cured. One technique for curing an epoxy-based underfill material as passivation material 130 is by heating structure 100.

FIG. 2 shows the structure of FIG. 1 following the removal of passivation material 130 to expose contact pad 220 and bring the blanket layer of underfill material to a plane of the contact pad (e.g., contact pad 220). FIG. 2 shows the structure with passivation material 130 surrounding contact pad 120. In one embodiment, passivation material 130 is ablated using temporally coherent electromagnetic radiation. For example, a pulsed-wave UV laser ablation technique, in one embodiment, uses a raster-based system that sequentially ablates passiavtion material 130 on wafer 110. The raster-based system sequentially ablates passivation material across wafer 110 until contact pads (e.g., contact pad 120) are exposed. A second laser ablation recipe may then optionally be used to clean the contact pads of any debris or oxide. A DXF file of a contact pad pattern on a specific device may be imported into a laser milling tool and a galvo system used to direct the laser energy only to the contact pad region.

Where a constant wave excimer laser is used, in one embodiment, such system uses a projection-based system where large areas of passivation material can be ablated sequentially until contact pads (e.g., contact pad 120) are exposed. In addition, once the contact pads are exposed, the pads may be cleaned of any residual debris or oxide using a second laser ablation recipe. A photomask of the contact pad pattern may be used or such second ablation to protect the underfill material around the exposed contact pads.

A pulsed-wave UV laser ablation recipe for removal of passivation material is shown in Table 1:

TABLE 1

Laser wavelength: 355 nm
Power: 2.5 to 3.7 mJ
Frequency (rep rate): 55 kHz
Galvo speed: 500 mm/s
Beam expansion: 10X (beam diameter ~40 μm)
Number of passes depends on thickness of underfill material over
contact pads that need to be removed

A pulsed-wave UV laser ablation recipe for cleaning copper contact pads is shown in Table 2:

TABLE 2

Laser wavelength: 355 nm
Power: 218 mJ
Frequency (rep rate): 32 kHz
Galvo speed: 210 mm/s
Laser spot size: 8 microns
Beam expansion: 10X (beam diameter ~40 μm)
A DXF file of the contact pad pattern is imported to the system and
galvo directs the laser beam to ablate only the copper contact pad
regions

Once passivation material 130 is brought to a plane of a surface of contact pad 120 or a desired level above the plane, a sacrificial material may be introduced and patterned to form openings to contact pads (e.g., contact pad 120) on wafer. FIG. 3 shows the structure of FIG. 2 following the introduction of sacrificial material 140 to a thickness suitable for solder introduction on the contact pads. In one embodiment, sacrificial material 140 is a linear material. A linear material as used herein is a material that does not include cross-linking agents or fillers that cross-link polymers of the material together when exposed to a photo (light) source. In this sense, linear materials include polymerizable materials including, but not limited to, materials that are susceptible to polymerization of monomers in the presence of light (e.g., UV light) without cross-linking agents or fillers. Examples of linear materials include organic materials such as acrylics, epoxies and polyimides. In another embodiment, sacrificial material 140 of a linear material may be introduced as a liquid in, for example, a spinning process and allowed to cure. In one embodiment, sacrificial material 140 is a non-linear material such as a photoresist material or dry film resist material. An example of such material is Riston™ commercially available from E.I. DuPont de Nemours and Company of Wilmington, Del. that may be introduced, for example, by a spinning process.

FIG. 4 shows the structure of FIG. 3 following the patterning of openings in sacrificial material 140 on wafer 110 to expose desired contact pads such as opening 145 to contact pad 120. Where sacrificial material 140 is a non-linear material such as a photoresist material, conventional photolithography techniques may be used to pattern sacrificial material 140. Such techniques include introducing the material by spin coating using light to transfer a pattern from a photomask to the light sensitive photoresist and then a developer to remove the unwanted material.

In an embodiment where sacrificial material 140 is a linear material, openings such as opening 145 to desired contact pacts (contact pad 120) on wafer 110 may be formed by ablation using temporally coherent electromagnetic radiation. Representatively, such temporally coherent electromagnetic radiation may be in the form of a pulsed-wave UV laser or a constant wave excimer laser radiation. The energy level associated with the laser is tailored to be lower than the laser damage threshold energies for copper and solder to allow sacrificial material 140 to be removed without damage to the contact pad.

A laser or photoablation process allows selective removal of polymeric materials through photochemical versus thermal ablation. An advantage of a photoablation process is depth control in the organic material and clean removal of the organic material. The “cold” photoablation process would require assist of photon energy in with UV spectrum, with photon energy above hydro-carbon bond breakage. From the literature, C—C bond breakage requires a photon energy of 3.6 electron-volts (eV) which suits UV 355 nm laser radiation (third harmonic of YAG laser), and for C—H bond 4.3 eV which suits deep UV 266 nm laser radiation (fourth harmonic of YAG laser). The “hot” or “thermal” ablation process required excitation of vibrational energy modes in lattice of hydro-carbonic molecule, where IR-UV lasers are all suited. An advantage of deep UV lasers is obvious since ablation will promote clean and residue-free ablation of hydro-carbonic material by means of all ablation mechanisms.

A pulsed-wave UV laser ablation recipe for selective removal of a sacrificial material of RISTON™ photoresist is shown in Table 3.

TABLE 3

Laser wavelength: 355 nm
Power: 15.5 to 16.0 mJ
Frequency (rep rate): 44 kHz
Galvo speed: 440 mm/s
Laser spot size: 32 microns
Number of passes depends on thickness of sacrificial material to be
removed.

Utilizing a process flow and mechanism involving a linear sacrificial material opens up options for materials that can be considered making it easier to meet the process requirements. This also simplifies the processing of the materials since only application and cure are required.

Using a sacrificial material that is a linear material of an organic material without cross-linking agents or fillers further allows for finer features to be defined in laser processing then with filled materials where the cross-linking agents or fillers can attenuate the light resulting in poorer definition particularly for thick films.

The ability to use fully cured sacrificial materials with laser ablation techniques still further allows for better process stability to thermal and chemical processing. Alternative cure processes can be utilized to minimize wafer warpage. For example, a UV cure polyimide could be used that would minimize the thermal processing used since the only thermal processing required will be reflow of the bump in the solder formation process.

A wider range of material can be considered since there are no requirements for photo sensitivity. This could allow for specific selection of polymeric materials that can be removed without damaging underlying organic materials such as underfill material and passivation stress buffer material which are typically filled in the case of underfill material.

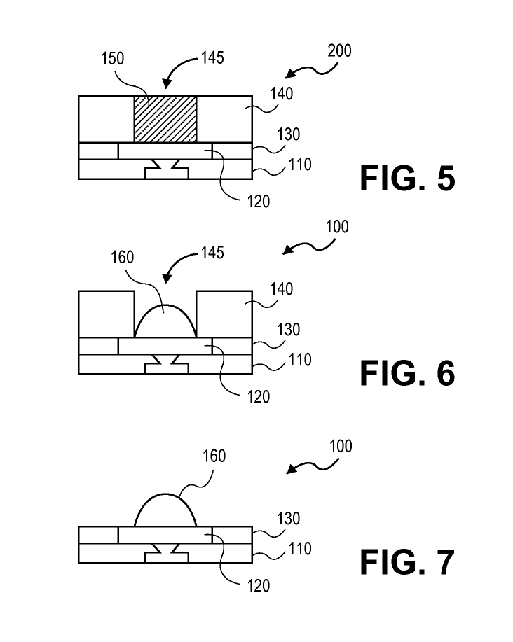

FIG. 5 shows sacrificial material 140 having opening 145 to contact pad 120. FIG. 5 also shows solder material 150 introduced into opening 145. Solder material 150 includes, but is not limited to, solder paste material, solder balls or plated solder.

FIG. 6 shows the structure of FIG. 5 following the formation of solder bump 160. One way solder bump 160 is formed is through heating structure 100 (solder reflow). Once solder bump 160 is formed, sacrificial material 140 may be removed by, for example, an aqueous or organic stripper or temporally coherent electromagnetic radiation such as a pulsed-wave UV or constant wave excimer laser operated as described above and at an energy below damage threshold energies for a material of the contact pads and a material of the solder.

FIG. 7 shows the structure of FIG. 6 following the removal of sacrificial material 140. Where the process described in FIGS. 1-7 is done at the wafer level, the wafer may now be diced into individual dice having contact pads including solder bumps (e.g., solder bump 160). An individual die may then be assembled into a package substrate.

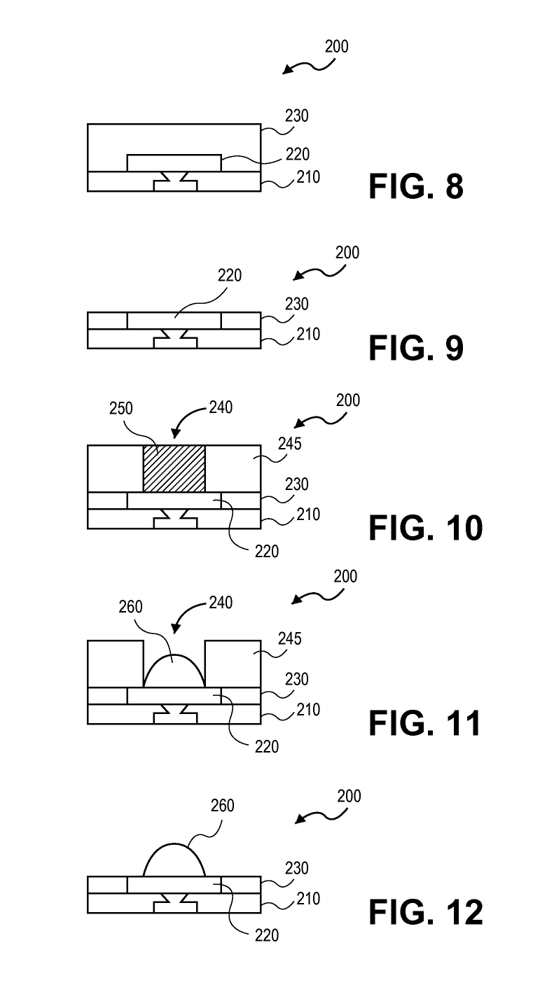

FIGS. 8-10 describe a second embodiment of introducing a passivation material on a wafer and using a laser ablation method to expose contact pads and planarize the passivation material. FIG. 8 shows structure 200 that is, for example, a side view portion of a wafer (e.g., a silicon wafer). FIG. 8 shows contact pad 220 on a surface of wafer 210. It is appreciated that wafer 210 may have thousands of similar contact pads across its surface. Contact pad 220 is, for example, a copper pad. Overlying contact pad 220 as a blanket over, for example, a surface of wafer 210 is passivation material 230. Passivation material 230 may be any of the passivation materials referenced above including an underfill material of, for example, an epoxy material or other materials noted above. In one embodiment, passivation material 230 of underfill material is introduced on the surface of wafer 210 and then cured with, for example, by heating structure 200.

FIG. 9 shows the structure of FIG. 8 following the removal of passivation material 230 to expose contact pad 220. In this embodiment, the removal involves a planarization of a surface of the structure to expose contact pad 220 and bring the blanket layer of passivation material 230 to a plane of the contact pad (e.g., contact pad 220). In one embodiment, removal of passivation material 230 involves ablation using temporally coherent electromagnetic radiation in a process such as described above. For example, a pulsed-wave UV laser ablation technique, in one embodiment, uses a raster-based system that sequentially ablates passivation material 230 on wafer 210. The raster-based system sequentially ablates passivation material across wafer 210 until contact pads (e.g., contact pad 220) are exposed. A second laser ablation recipe may then optionally be used to clean the contact pads of any debris or oxide. A DXF file of a contact pad pattern on a specific device may be imported into a laser milling tool and a galvo system used to direct the laser energy only to the contact pad region.

Where a constant wave excimer laser is used, in one embodiment, such system uses a projection-based system where large areas of passivation material can be ablated sequentially until contact pads (e.g., contact pad 220) are exposed. In addition, once the contact pads are exposed, the pads may actually be cleaned of any residual debris or oxide using a second laser ablation recipe. A photomask of the contact pad pattern may be used or such second ablation to protect the passivation material around the exposed contact pads.

A pulsed-wave UV laser ablation recipe for removal of an amine epoxy underfill material as a passivation material is shown in Table 4:

TABLE 4

Laser wavelength: 355 nm
Power: 2.5 to 3.7 mJ
Frequency (rep rate): 55 kHz
Galvo speed: 500 mm/s
Spot size: 8 microns
Beam expansion: 10X (beam diameter ~40 μm)
Number of passes depends on thickness of underfill material over
contact pads that need to be removed

A pulsed-wave UV laser ablation recipe for cleaning copper contact pads is shown in Table 5:

TABLE 5

Laser wavelength: 355 nm
Power: 218 mJ
Frequency (rep rate): 32 kHz
Galvo speed: 210 mm/s
Laser spot size: 8 microns
Beam expansion: 10X (beam diameter ~40 μm)
A DXF file of the contact pad pattern is imported to the system
and galvo directs the laser beam to ablate only the copper
contact pad regions

Once passivation material 230 is brought to a plane of a surface of contact pad 220 or a desired level above the plane, a sacrificial material may be introduced and patterned to form openings to contact pads (e.g., contact pad 220) on wafer. A representative sacrificial material is a photoresist material. FIG. 10 shows sacrificial material 245 introduced and patterned on underfill material 230 of wafer 210. Sacrificial material 245 is patterned to have opening to desired contact pads. FIG. 10 shows sacrificial material 245 having opening 240 to contact pad 220. Following the introduction and patterning of sacrificial material 245, solder material 250 is introduced into opening 240.

FIG. 11 shows the structure of FIG. 10 following the formation of solder bump 260. One way solder bump 260 is formed is through heating structure 200 (solder reflow). Once solder bump 260 is formed, sacrificial material 245 may be removed by, for example, an aqueous or organic stripper or temporally coherent electromagnetic radiation such as a pulsed-wave UV or excimer laser operated as described above and at an energy below damage threshold energies for a material of the contact pads and a material of the solder.

A pulsed-wave UV laser ablation recipe for selective removal of RISTON™ photoresist material (commercially available from E.I. DuPont de Nemours and Company of Wilmington, Del.) is shown in Table 6.

TABLE 6

Laser wavelength: 355 nm
Power: 15.5 to 16.0 mJ
Frequency (rep rate): 44 kHz
Galvo speed: 440 mm/s
Laser spot size: 32 microns
Number of passes depends on thickness of sacrificial material
to be removed.

FIG. 12 shows the structure of FIG. 11 following the removal of photoresist material 245. Where the process described in FIGS. 8-12 is done at the wafer level, the wafer may now be diced into individual dice having contact pads including solder bumps (e.g., solder bump 260). An individual die may then be assembled into a package substrate.

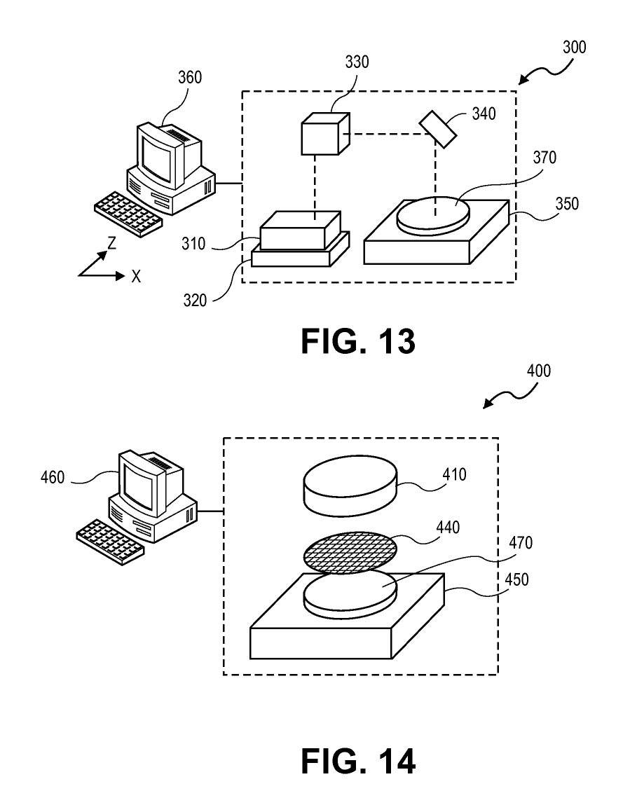

In the above embodiments, methods for removing or ablating materials (e.g., passivation material, sacrificial material) included ablation using temporally coherent radiation was described. Specific examples of providing such temporally coherent radiation included through a pulsed-wave UV laser ablation process and a constant wave excimer projection laser process. FIG. 13 shows a schematic, perspective top, side view of a system for conducting a pulsed-wave UV laser ablation process. Referring to FIG. 13, system 300 includes pulsed-wave UV laser 310 connected to servomechanism 320 that controls a mechanical position in at least an XZ direction of laser 310. Laser 310 directs electromagnetic radiation in the form of a beam to galvanometer 330 that steers the beam toward stage 350. Mirror 340 may be disposed between galvanometer 330 and stage 350 to, for example, collimate the radiation. A DXF file of a pad pattern for structure 100 is transferred from computer 360 to system 300 and non-transitory machine readable instructions stored in computer 360 may be executed to direct a laser ablation process of material on wafer 370 on stage 350 of the system.

FIG. 14 shows a schematic perspective top, side view of a system employing a constant wave excimer projection laser. Referring to FIG. 14, system 400 includes laser 410 with an output disposed above wafer 470 (e.g., wafer) on stage 450. Disposed between laser 410 and wafer 470 is photomask 440. Photomask 440, in one embodiment, includes a contact pad pattern to protect the material around contact pads of wafer from ablation and expose areas of material over contact pads. The ablation of the underfill material by way of a constant wave excimer laser may be directed by computer 460 that contains non-transitory executable machine-readable instructions to direct laser 410.

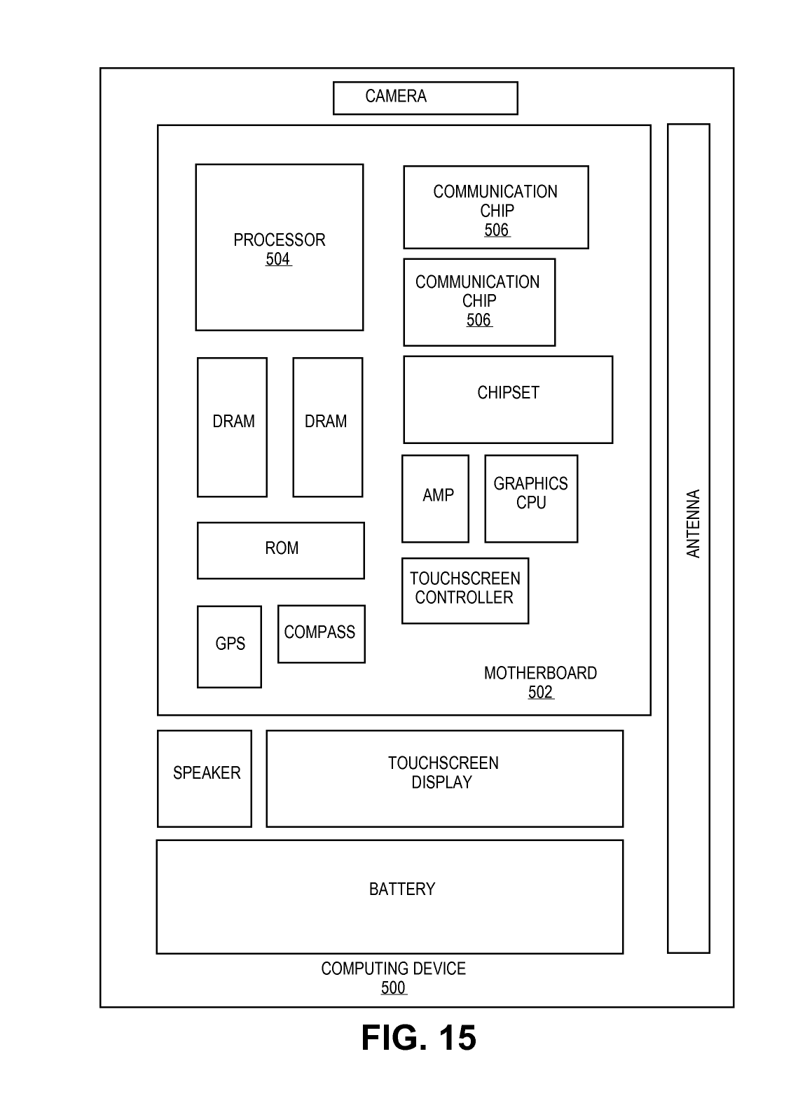

FIG. 15 illustrates a computing device 500 in accordance with one implementation. Computing device 500 houses board 502. Board 502 may include a number of components, including but not limited to processor 504 and at least one communication chip 506. Processor 504 is physically and electrically connected to board 502 through, for example, a package substrate. Processor 504 is a die including solder bumps on contact pads, formed as described above, to connect to the package substrate. In some implementations the at least one communication chip 506 is also physically and electrically coupled to board 502. In further implementations, communication chip 506 is part of processor 504.

Depending on its applications, computing device 500 may include other components that may or may not be physically and electrically coupled to board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communication chip 506 enables wireless communications for the transfer of data to and from computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

In various implementations, computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 500 may be any other electronic device that processes data.

### EXAMPLES

The following examples pertain to embodiments.

Example 1 is a method including introducing a passivation material over contact pads on a surface of an integrated circuit substrate; patterning a sacrificial material on the passivation material to define openings in the sacrificial material to the contact pads; introducing solder to the contact pads; and after introducing the solder, removing the sacrificial material with the proviso that, where the sacrificial material is a non-linear material, removing includes using temporally coherent electromagnetic radiation.

In Example 2, the sacrificial material in the method of Example 1 is a linear material and patterning the sacrificial material to define openings to the contact pads includes ablating with temporally coherent electromagnetic radiation.

In Example 3, the sacrificial material in the method of Example 1 is a linear material and removing the sacrificial material includes using temporally coherent electromagnetic radiation.

In Example 4, the sacrificial material in the method of Example 1 is a non-linear material.

In Example 5, the temporally coherent electromagnetic radiation in the method of Example 1 is provided by a pulsed wave ultraviolet laser.

In Example 6, the temporally coherent electromagnetic radiation in the method of Example 1 is provided by a constant wave excimer projection laser.

In Example 7, introducing the solder in the method of Example 1 includes introducing a solder paste or solder ball and reflowing.

In Example 8, prior to patterning the sacrificial material on the passivation material in the method of Example 1, the method includes ablating the passivation material to a thickness of the contact pads using temporally coherent electromagnetic radiation.

In Example 9, any of the methods of Examples 1-8 are used in the formation of an integrated circuit substrate such as a microprocessor including contact pads for connection to a package.

Example 10 is a method including introducing a passivation material over contact pads on a surface of an integrated circuit substrate; exposing the contact pads; patterning a non-linear material on the passivation material to define openings in the photosensitive material to the exposed contact pads; introducing solder to the contact pads; and after introducing the solder, removing the non-linear material using temporally coherent electromagnetic radiation.

In Example 11, the temporally coherent electromagnetic radiation in the method of Example 10 is provided by a pulsed wave ultraviolet laser.

In Example 12, the temporally coherent electromagnetic radiation in the method of Example 10 is provided by a constant wave excimer projection laser.

In Example 13, the temporally coherent electromagnetic radiation in the method of Example 10 is administered at an energy level lower than the damage threshold energy for solder and the contact pads.

In Example 14, exposing the contact pads in the method of Example 10 includes ablating the passivation material to a thickness of the contact pads using temporally coherent electromagnetic radiation.

In Example 15, any of the methods of Examples 10-14 are used in the formation of an integrated circuit substrate such as a microprocessor including contact pads for connection to a package.

Example 16 is a method including introducing a passivation material over contact pads on a surface of an integrated circuit substrate; exposing the contact pads; patterning a linear material on the passivation material to define openings in the linear material to the exposed contact pads; introducing solder to the contact pads; and after introducing the solder, removing the linear material.

In Example 17, removing the linear material in the method of Example 16 includes removing using temporally coherent electromagnetic radiation.

In Example 18, the temporally coherent electromagnetic radiation in the method of Example 16 is provided by a pulsed wave ultraviolet laser.

In Example 19, the temporally coherent electromagnetic radiation in the method of Example 16 is provided by a constant wave excimer projection laser.

In Example 20, the temporally coherent electromagnetic radiation in the method of Example 16 is administered at an energy level lower than the damage threshold energy for solder and the contact pads.

In Example 21, exposing the contact pads in the method of Example 16 includes ablating the passivation material to a thickness of the contact pads using temporally coherent electromagnetic radiation.

In Example 22, any of the methods of Examples 16-21 are used in the formation of an integrated circuit substrate such as a microprocessor including contact pads for connection to a package.

In the description above, for the purposes of explanation, numerous specific details have been set forth in order to provide a thorough understanding of the embodiments. It will be apparent however, to one skilled in the art, that one or more other embodiments may be practiced without some of these specific details. The particular embodiments described are not provided to limit the invention but to illustrate it. The scope of the invention is not to be determined by the specific examples provided above but only by the claims below. In other instances, well-known structures, devices, and operations have been shown in block diagram form or without detail in order to avoid obscuring the understanding of the description. Where considered appropriate, reference numerals or terminal portions of reference numerals have been repeated among the figures to indicate corresponding or analogous elements, which may optionally have similar characteristics.

It should also be appreciated that reference throughout this specification to “one embodiment”, “an embodiment”, “one or more embodiments”, or “different embodiments”, for example, means that a particular feature may be included in the practice of the invention. Similarly, it should be appreciated that in the description various features are sometimes grouped together in a single embodiment, figure, or description thereof for the purpose of streamlining the disclosure and aiding in the understanding of various inventive aspects. This method of disclosure, however, is not to be interpreted as reflecting an intention that the invention requires more features than are expressly recited in each claim. Rather, as the following claims reflect, inventive aspects may lie in less than all features of a single disclosed embodiment. Thus, the claims following the Detailed Description are hereby expressly incorporated into this Detailed Description, with each claim standing on its own as a separate embodiment of the invention.

What is claimed is:

1. A method comprising:
introducing a passivation material over contact pads on a surface of an integrated circuit substrate;
patterning a sacrificial material on the passivation material to define openings in the sacrificial material to the contact pads;
introducing solder to the contact pads; and
after introducing the solder, removing the sacrificial material with the proviso that, where the sacrificial material is a non-linear material, removing comprises using temporally coherent electromagnetic radiation.

2. The method of claim 1, wherein the sacrificial material is a linear material and patterning the sacrificial material to define openings to the contact pads comprises ablating with temporally coherent electromagnetic radiation.

3. The method of claim 1, wherein the sacrificial material is a linear material and removing the sacrificial material comprises using temporally coherent electromagnetic radiation.

4. The method of claim 1, wherein the sacrificial material is a non-linear material.

5. The method of claim 1, wherein the temporally coherent electromagnetic radiation is provided by a pulsed wave ultraviolet laser.

6. The method of claim 1, wherein introducing the solder comprises introducing a solder paste or solder ball and reflowing.

7. The method of claim 1, wherein prior to patterning the sacrificial material on the passivation material, ablating the passivation material to a thickness of the contact pads using temporally coherent electromagnetic radiation.

8. A method comprising:
introducing a passivation material over contact pads on a surface of an integrated circuit substrate;
exposing the contact pads;
patterning a non-linear material on the passivation material to define openings in the photosensitive material to the exposed contact pads;
introducing solder to the contact pads; and
after introducing the solder, removing the non-linear material using temporally coherent electromagnetic radiation.

9. The method of claim 8, wherein the temporally coherent electromagnetic radiation is provided by a pulsed wave ultraviolet laser.

10. The method of claim 8, wherein the temporally coherent electromagnetic radiation is administered at an energy level lower than the damage threshold energy for solder and the contact pads.

11. The method of claim 8, wherein exposing the contact pads comprises ablating the passivation material to a thickness of the contact pads using temporally coherent electromagnetic radiation.

12. A method comprising:
introducing a passivation material over contact pads on a surface of an integrated circuit substrate;
exposing the contact pads;
patterning a linear material on the passivation material to define openings in the linear material to the exposed contact pads;
introducing solder to the contact pads; and
after introducing the solder, removing the linear material.

13. The method of claim 12, wherein removing the linear material comprises removing using temporally coherent electromagnetic radiation.

14. The method of claim 12, wherein the temporally coherent electromagnetic radiation is provided by a pulsed wave ultraviolet laser.

15. The method of claim 12, wherein the temporally coherent electromagnetic radiation is administered at an energy level lower than the damage threshold energy for solder and the contact pads.

16. The method of claim 12, wherein exposing the contact pads comprises ablating the passivation material to a thickness of the contact pads using temporally coherent electromagnetic radiation.
